(19) United States
(12) Patent Application Publication
(10) Pub. No.: US 2024/0372320 A1
(43) Pub. Date: Nov. 7, 2024

(54) DML DRIVER

(71) Applicants: Nippon Telegraph and Telephone Corporation, Tokyo (JP); NTT Innovative Devices Corporation, Yokohama-shi (JP)

(72) Inventors: Toshiki Kishi, Tokyo (JP); Tadashi Minotani, Tokyo (JP); Yoshikazu Urabe, Yokohama-shi (JP); Nobuhiro Toyoda, Yokohama-shi (JP); Masatoshi Tobayashi, Yokohama-shi (JP)

(21) Appl. No.: 18/688,616

(22) PCT Filed: Sep. 3, 2021
(86) PCT No.: PCT/JP2021/032397

§ 371 Date: Mar. 1, 2024

(51) Int. Cl. H01S 5/042; H01S 5/40

(52) U.S. Cl. CPC H01S 5/0427; H01S 5/4025

(57) ABSTRACT

An embodiment is a directly modulated laser (DML) driver, including a PMOS transistor having a source connected to a first power supply terminal and a drain connected to an anode of a laser diode, an NMOS transistor having a gate configured to be connected to an modulated input signal, and a source connected to a second power supply terminal, a resistor having one end connected to a first bias terminal, and the other end connected to the gate of the PMOS transistor, a first decoupling capacitor having one end connected to the first power supply terminal, and the other end connected to the second power supply terminal, and a plurality of decoupling capacitors each having one end connected to a respective bias terminal, and the other end connected to the first power supply terminal.

### CROSS-REFERENCE TO RELATED APPLICATIONS

This application is a national phase entry of PCT Application No. PCT/JP2021/032397, filed on Sep. 3, 2021, which application is hereby incorporated herein by reference.

### TECHNICAL FIELD

The present invention relates to a technique of driving a directly modulated laser (DML) and, more particularly, to a DML driver capable of suppressing deterioration of the output waveform of a driver at the time of multichannel driving.

### BACKGROUND

These days, the traffic amount of communication is increasing year by year around the world along with a remarkable spread of SNS (Social Networking Service). A further increase in traffic amount is expected in the future because of the development of IoT (Internet of Things) and cloud computing technologies. To cope with an enormous traffic amount, large communication capacities inside and outside data centers are required.

As the capacity increases, standardization of 100 GbE is complete at present in the Ethernet® standard, which is a main standard component of a network, and standardization of 400 GbE aiming at larger capacities is being discussed. For application to 400 GbE, a driver using DML is drawing attention in terms of low power consumption (see Non-Patent Literature 1).

FIG. 10 is a circuit diagram showing the arrangement of a conventional DML driver. The DML driver includes a PMOS transistor M₁ₚ having a source connected to a power supply voltage V₁, and a drain connected to the anode of a laser diode (LD) 1; an NMOS transistor M₁ₙ having a gate to which a modulated signal Vᵢₙ is input, and a source connected to ground; an NMOS transistor M₂ₙ having a drain connected to the drain of the PMOS transistor M₁ₚ and the anode of the LD 1, and a source connected to the drain of the NMOS transistor M₁ₙ; a resistor R₂ having one end connected to a bias voltage V₂, and the other end connected to the gate of the PMOS transistor M₁ₚ; a resistor R₃ having one end connected to a bias voltage V₃, and the other end connected to the gate of the NMOS transistor M₂ₙ; a resistor R₄ having one end connected to a bias voltage V₄, and the other end connected to the gate of the NMOS transistor M₁ₙ; a decoupling capacitor C₁ having one end connected to the power supply voltage V₁, and the other end connected to ground; a decoupling capacitor C₂ having one end connected to the bias voltage V₂, and the other end connected to ground; a decoupling capacitor C₃ having one end connected to the bias voltage V₃, and the other end connected to ground; and a decoupling capacitor C₄ having one end connected to the bias voltage V₄, and the other end connected to ground.

The NMOS transistors M₁ₙ and M₂ₙ are cascode-connected. The cascode connection improves the frequency characteristic compared to the single NMOS transistor M₁ₙ. Even when the operating voltage of the LD 1 exceeds the breakdown voltage of the single NMOS transistor, it is divided by the cascode connection and the voltage breakdown of the NMOS transistors M₁ₙ and M₂ₙ can be prevented. The decoupling capacitor C₁ stabilizes the power supply voltage V₁. The resistor R₂ and the decoupling capacitor C₂ stabilize the bias voltage V₂. The resistor R₃ and the decoupling capacitor C₃ stabilize the bias voltage V₃. The decoupling capacitor C₄ stabilizes the bias voltage V₄. The resistor R₄ is an impedance matching resistor.

When power supplies that supply corresponding the power supply voltage V₁ and the bias voltages V₂ to V₄ are connected to a driver IC via cables, a substrate, and the like, the parasitic inductance and the parasitic resistance need to be considered. FIG. 11 shows a conventional circuit arrangement including the parasitic component of each power supply. In the example of FIG. 11, a parasitic inductance L_{w1} and a parasitic resistance R_{w1} are series-connected to the V₁ power supply, and a parasitic inductance L_{w2} and a parasitic resistance R_{w2} are series-connected to the V₂ power supply. A parasitic inductance L_{w3} and a parasitic resistance R_{w3} are series-connected to the V₃ power supply, and a parasitic inductance L_{w4} and a parasitic resistance R_{w4} are series-connected to the V₄ power supply. In FIG. 11, parasitic capacitances present between the terminals of a DML driver to which the parasitic inductances L_{w1} to L_{w4} are connected and the ground are not illustrated.

Here, attention is paid to the V₁ power supply line through which a current flows. An impedance Zᵥ₁(s) of the source of the PMOS transistor M₁ₚ is represented by a Laplace function given by equation (1):

$${Z}_{V 1} ( s ) = \frac{1}{\frac{1}{{L}_{W 1} s + {R}_{W 1}} + {C}_{1} s} \qquad ( 1 )$$

where s is the Laplace operator. Since no load impedance is series-connected to the source of the PMOS transistor M₁ₚ in the circuit, Zᵥ₁(s) in equation (1) directly serves as the load impedance of the V₁ power supply and causes the resonance of the power supply line.

In the examples of FIGS. 10 and 11, an arrangement for one channel is shown. When an LD array of a plurality of channels and DML drivers of a plurality of channels are prepared, and the DML drivers of a plurality of channels are driven by a multistage PRBS (Pseudo Random Bit Sequence) signal, the V₁ power supply is shared between the DML drivers of the respective channels. Similarly, the V₂ to V₄ power supplies are also shared between the DML drivers of the respective channels.

When the DML drivers sharing the power supply are multichannel-driven by the multistage PRBS signal, the waveform is deteriorated by an impedance increasing on the V₁ power supply line owing to crosstalk between channels. If the decoupling capacitor C₁ has an extremely large value, the waveform deterioration can be satisfactorily suppressed. However, it is difficult to fabricate a capacitor of an extremely large value within an IC. Only the decoupling capacitor C₁ cannot suppress an increase in low-frequency impedance, and is not enough as a waveform deterioration measure in multichannel driving of the multistage PRBS signal.

### RELATED ART LITERATURE

### Non-Patent Literature

Non-Patent Literature 1: T.Kishi et al., “A 137-mW, 4 ch×25-Gbps low-power compact transmitter flip-chip-bonded 1.3-μm LD-array-on-Si”, In Proceedings of the Optical Fiber Communication Conference and Exhibition, 2018, Paper M2D.2.

### SUMMARY

### Problem to be Solved

The embodiments of the present invention have been made to solve the above-described problems, and has as its object to provide a DML driver capable of suppressing an increase in the impedance of a power supply line, and suppressing deterioration of the output waveform.

### Means of Solution to the Problem

A DML driver according to embodiments of the present invention comprises a first transistor having a source or emitter connected to a first power supply voltage, and a drain or collector connected to an anode of a laser diode; a second transistor having a gate or base to which a signal is input, a drain or collector connected to the anode of the laser diode, and a source or emitter connected to a second power supply voltage; a first resistor having one end connected to a first bias voltage, and the other end connected to a gate or base of the first transistor; a second resistor having one end connected to a second bias voltage, and the other end connected to a gate or base of the second transistor; a first decoupling capacitor having one end connected to the first power supply voltage, and the other end connected to the second power supply voltage; a second decoupling capacitor having one end connected to the first bias voltage, and the other end connected to the first power supply voltage; a third decoupling capacitor having one end connected to the gate or base of the first transistor, and the other end connected to the first power supply voltage; and a fourth decoupling capacitor having one end connected to the second bias voltage, and the other end connected to the first power supply voltage.

An arrangement example of the DML driver according to embodiments of the present invention further comprises a third transistor cascode-connected between the anode of the laser diode and the drain or collector of the second transistor; a third resistor having one end connected to a third bias voltage, and the other end connected to a gate or base of the third transistor; a fifth decoupling capacitor having one end connected to the third bias voltage, and the other end connected to the first power supply voltage; and a sixth decoupling capacitor having one end connected to the gate or base of the third transistor, and the other end connected to the first power supply voltage.

An arrangement example of the DML driver according to embodiments of the present invention further comprises a fourth transistor cascode-connected between the drain or collector of the first transistor and the anode of the laser diode; a fourth resistor having one end connected to a fourth bias voltage, and the other end connected to a gate or base of the fourth transistor; a seventh decoupling capacitor having one end connected to the fourth bias voltage, and the other end connected to the first power supply voltage; and an eighth decoupling capacitor having one end connected to the gate or base of the fourth transistor, and the other end connected to the first power supply voltage.

An arrangement example of the DML driver according to embodiments of the present invention further comprises a fifth resistor inserted between the first power supply voltage and the source or emitter of the first transistor.

### Effect of Embodiments of the Invention

According to embodiments of the present invention, an increase in the impedance of a power supply line can be suppressed. Thus, when DML drivers sharing the power supply are multichannel-driven, the inter-channel crosstalk can be suppressed to suppress the resonance of the power supply line at low frequencies and suppress deterioration of the output waveform.

### BRIEF DESCRIPTION OF THE DRAWINGS

FIG. 1 is a circuit diagram showing the arrangement of a DML driver according to the first embodiment of the present invention;

FIG. 2 is circuit diagram showing the parasitic component of each power supply of the DML driver according to the first embodiment of the present invention;

FIG. 3 is a graph showing results of simulating the EO response characteristic of the DML driver and LD for a conventional arrangement and the first embodiment of the present invention;

FIG. 4 is a graph showing results of simulating the group delay characteristic of the DML driver and LD for the conventional arrangement and the first embodiment of the present invention;

FIG. 5 is a graph showing results of simulating the inter-channel crosstalk characteristic of the DML driver for the conventional arrangement and the embodiment;

FIG. 6 is a circuit diagram showing the multichannel arrangement of DML drivers according to the first embodiment of the present invention;

FIG. 7 shows charts showing results of simulating the optical output waveform of the LD for the conventional arrangement and the embodiment;

FIG. 8 is a circuit diagram showing the arrangement of a DML driver according to the second embodiment of the present invention;

FIG. 9 is a circuit diagram showing the arrangement of a DML driver according to the third embodiment of the present invention;

FIG. 10 is a circuit diagram showing the arrangement of a conventional DML driver; and

FIG. 11 is a circuit diagram showing the parasitic component of each power supply of the conventional DML driver.

### DETAILED DESCRIPTION OF ILLUSTRATIVE EMBODIMENTS

### Principle of Invention

According to embodiments of the present invention, the connection destination of the decoupling capacitor of each power supply line is changed from ground to a power supply voltage V₁. Compared to a conventional circuit arrangement, an increase in the impedance of a power supply line at low frequencies can be suppressed to suppress deterioration of the output waveform.

### First Embodiment

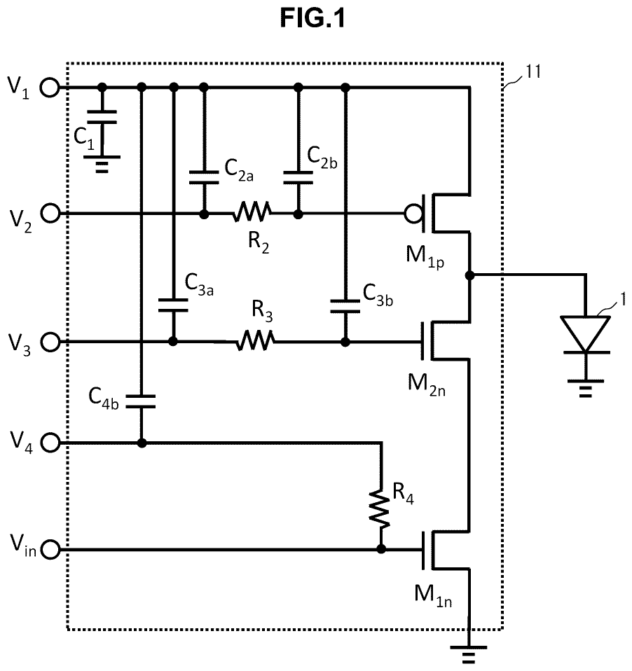

Embodiments of the present invention will be described below with reference to the accompanying drawings. FIG. 1 is a circuit diagram showing the arrangement of a DML driver according to the first embodiment of the present invention. A DML driver 11 according to the embodiment includes a PMOS transistor M₁ₚ having a source connected to a power supply voltage V₁ (first power supply voltage), and a drain connected to the anode of an LD 1; an NMOS transistor M₁ₙ having a gate to which a modulated signal Vᵢₙ is input, and a source connected to ground (second power supply voltage); an NMOS transistor M₂ₙ having a drain connected to the drain of the PMOS transistor M₁ₚ and the anode of the LD 1, and a source connected to the drain of the NMOS transistor M₁ₙ; a resistor R₂ having one end connected to a bias voltage V₂ (first bias voltage), and the other end connected to the gate of the PMOS transistor M₁ₚ; a resistor R₃ having one end connected to a bias voltage V₃ (third bias voltage), and the other end connected to the gate of the NMOS transistor M₂ₙ; a resistor R₄ having one end connected to a bias voltage V₄ (second bias voltage), and the other end connected to the gate of the NMOS transistor M₁ₙ; a decoupling capacitor C₁ having one end connected to the power supply voltage V₁, and the other end connected to ground; a decoupling capacitor C₂ₐ having one end connected to the bias voltage V₂, and the other end connected to the power supply voltage V₁; a decoupling capacitor C_{2b} having one end connected to the gate of the PMOS transistor M₁ₚ, and the other end connected to the power supply voltage V₁; a decoupling capacitor C₃ₐ having one end connected to the bias voltage V₃, and the other end connected to the power supply voltage V₁; a decoupling capacitor C_{3b} having one end connected to the gate of the NMOS transistor M₂ₙ, and the other end connected to the power supply voltage V₁; and a decoupling capacitor C_{4b} having one end connected to the bias voltage V₄, and the other end connected to the power supply voltage V₁.

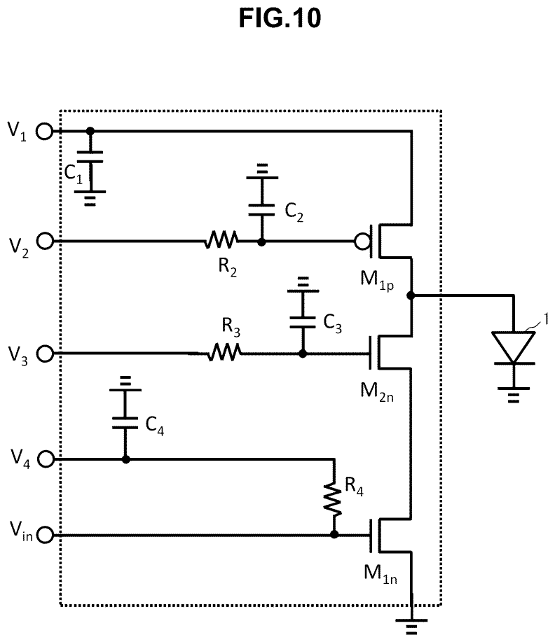

These voltages have a magnitude relationship: V₁>V₂>V₃>V₄>GND (ground). In the embodiment, to suppress the resonance of the V₁ power supply line, the decoupling capacitors C_{2b}, C_{3b}, and C_{4b} are constituted by changing the connection destinations of the decoupling capacitors C₂, C₃, and C₄ in FIG. 10 from ground to the power supply voltage V₁. Further, to enhance the suppression of the resonance, the decoupling capacitors C₂ₐ and C₃ₐ are added to the V₂ and V₃ power supply lines, and connected to the power supply voltage V₁.

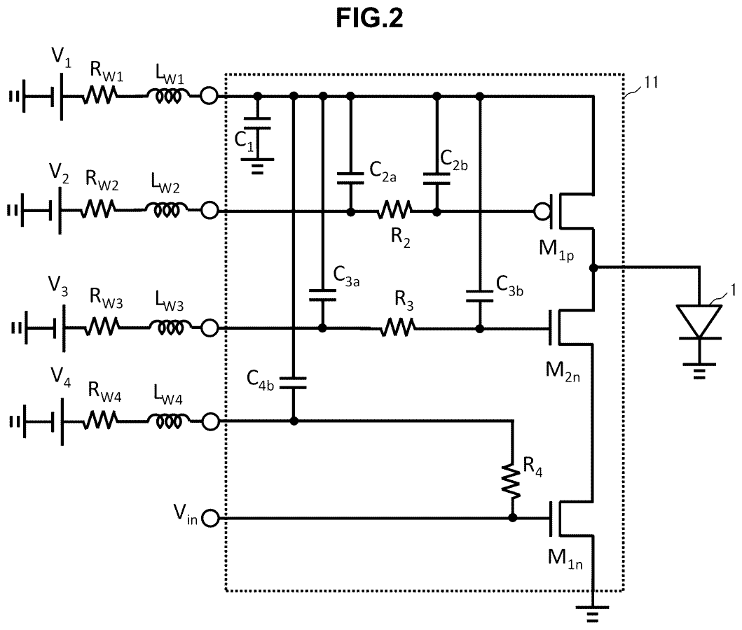

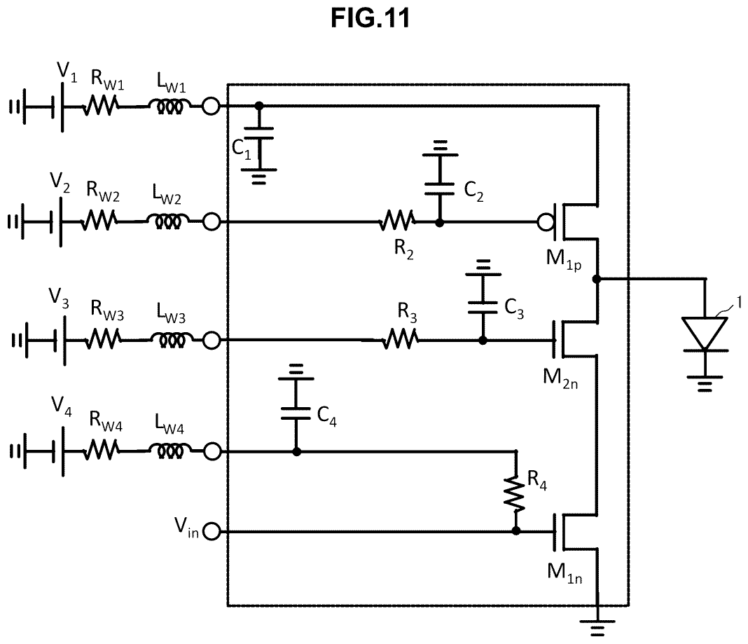

FIG. 2 shows the circuit arrangement of the embodiment including the parasitic component of each power supply. Similar to the case of FIG. 11, attention is paid to the V₁ power supply line through which a current flows. An impedance Zᵥ₁(s) of the source of the PMOS transistor M₁ₚ is represented by a Laplace function given by equation (2):

$${Z}_{V 1} ( s ) = \frac{1}{A} \qquad ( 2 )$$

$$A = \frac{1}{{L}_{W 1} s + {R}_{W 1}} + {C}_{1} s + \frac{1}{\frac{1}{{C}_{4 b} s} + {L}_{W 4} s + {R}_{W 4}} + \frac{1}{\frac{1}{{C}_{3 a} s + \frac{1}{\frac{1}{{C}_{3 b} s} + {R}_{3}}} + {L}_{W 3} s + {R}_{W 3}} + \frac{1}{\frac{1}{{C}_{2 a} s + \frac{1}{\frac{1}{{C}_{2 b} s} + {R}_{2}}} + {L}_{W 2} s + {R}_{W 2}}$$

A comparison between equations (1) and (2) reveals that the impedance Zᵥ₁(s) of the source of the PMOS transistor M₁ₚ can be reduced according to the embodiment.

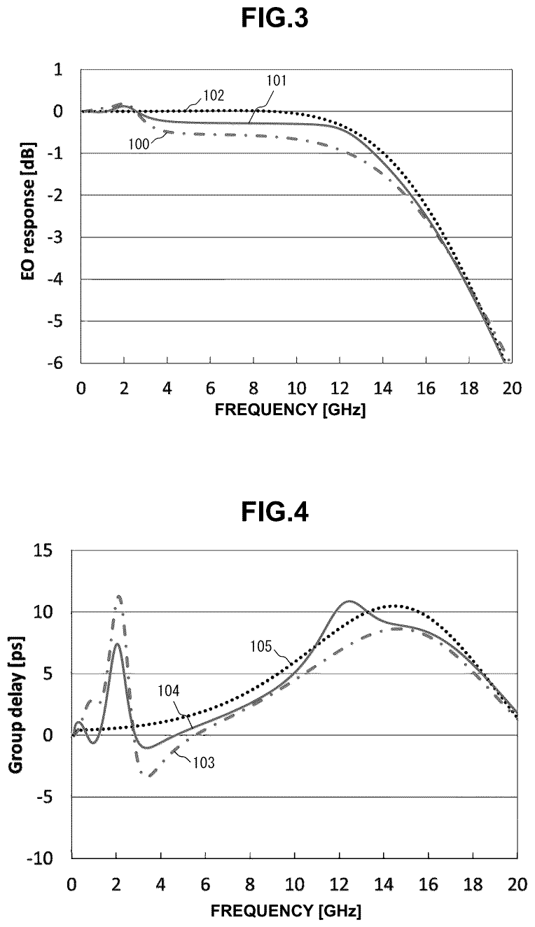

FIG. 3 shows results of simulating the EO (Electrical-to-Optical) response characteristic of the DML driver and LD 1 for the conventional arrangement and the embodiment. In FIG. 3, reference numeral 100 denotes an EO response characteristic in the conventional arrangement shown in FIG. 10; 101, an EO response characteristic in the embodiment; and 102, an EO response characteristic in an ideal state in which the parasitic component of each power supply is removed from the arrangement of the embodiment. As is apparent from FIG. 3, according to the embodiment, the resonance of the power supply line at low frequencies can be suppressed, obtaining a result close to the ideal state.

FIG. 4 shows results of simulating the group delay characteristic of the DML driver and LD 1 for the conventional arrangement and the embodiment. In FIG. 4, reference numeral 103 denotes a group delay characteristic in the conventional arrangement; 104, a group delay characteristic in the embodiment; and 105, a group delay characteristic in the ideal state in which the parasitic component of each power supply is removed from the arrangement of the embodiment. As is apparent from FIG. 4, the group delay characteristic at low frequencies is improved in the embodiment, compared to the conventional circuit arrangement.

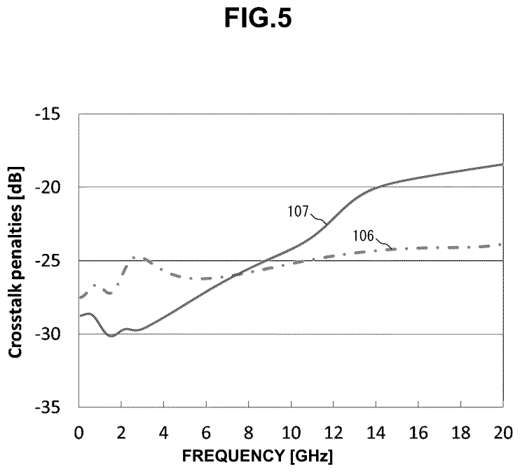

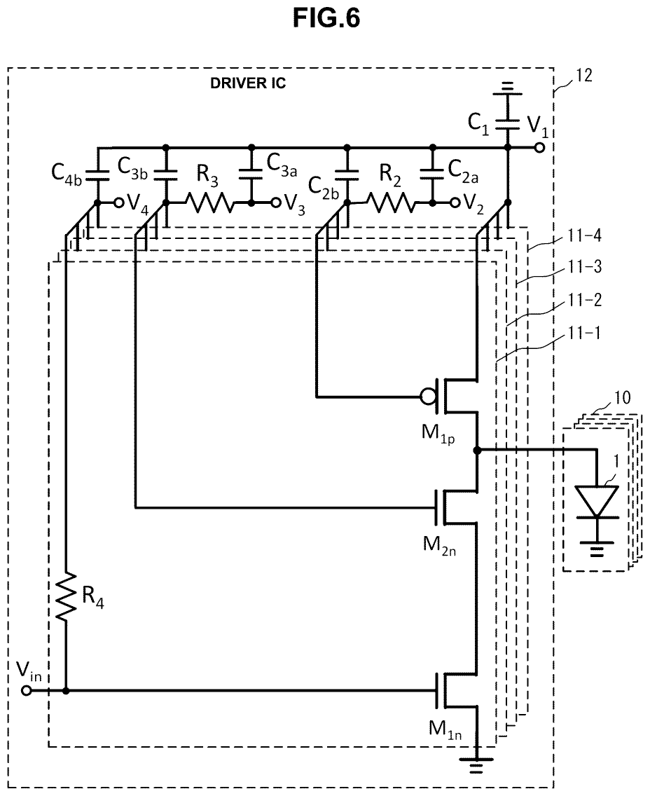

FIG. 5 shows results of simulating the inter-channel crosstalk characteristic of the DML driver for the conventional arrangement and the embodiment. In FIG. 5, reference numeral 106 denotes an inter-channel crosstalk characteristic in the conventional arrangement; and 107, an inter-channel crosstalk characteristic in the embodiment. A circuit diagram in which the conventional DML driver shown in FIG. 10 has a multichannel arrangement is disclosed in Non-Patent Literature 1. FIG. 6 is a circuit diagram showing the multichannel arrangement of the DML driver according to the embodiment.

The examples of Non-Patent Literature 1 and FIG. 6 show a 4-channel arrangement. DML drivers 11-1 to 11-4 for four channels that drive respective LDs 1 are provided in a driver IC (Integrated Circuit) 12 for an LD array 10 including the LDs 1 for four channels. The resistors R₂ and R₃ and the decoupling capacitors C₁, C₂ₐ, C_{2b}, C₃ₐ, C_{3b}, and C_{4b} are provided in the driver IC 12 commonly for the respective channels. The DML drivers 11-1 to 11-4 share the V₁ to V₄ power supplies, the resistors R₂ and R₃, and the decoupling capacitors C₁, C₂ₐ, C_{2b}, C₃ₐ, C_{3b}, and C_{4b}.

FIG. 5 shows results of obtaining a loss generated by the crosstalk between adjacent channels in the multichannel arrangement. As is apparent from FIG. 5, the loss at low frequencies is reduced in the embodiment, compared to the conventional circuit arrangement.

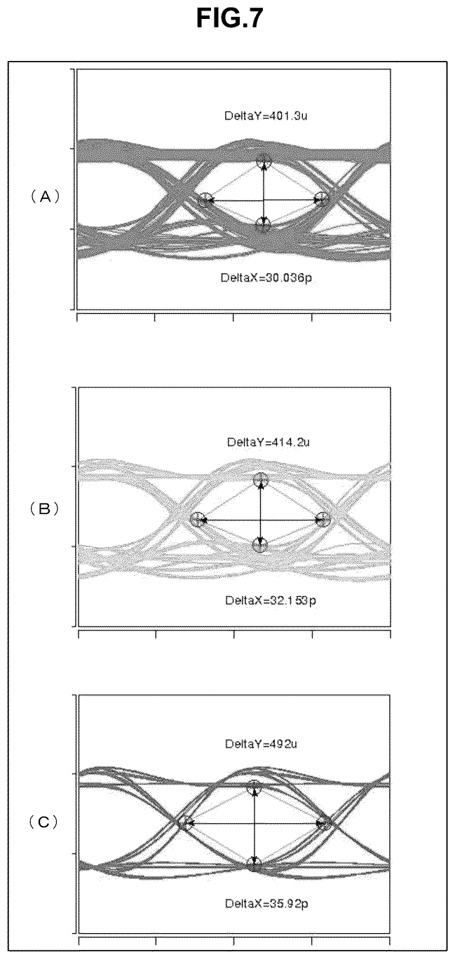

FIGS. 7(A) to 7(C) show results of simulating the optical output waveform of the LD 1 at the time of multichannel simultaneous driving for the conventional arrangement and the embodiment. The scale of the amplitude along the ordinate is 500 μW/div, and that of the time along the abscissa is 20 ps/div. FIG. 7(A) shows an optical output waveform when the conventional arrangement is used, FIG. 7(B) shows an optical output waveform when the arrangement of the embodiment is used, and FIG. 7(C) shows an optical output waveform in the ideal state in which the parasitic component of each power supply is removed from the arrangement of the embodiment. A comparison between FIGS. 7(A) and 7(B) reveals that the optical output waveform is improved by about 2 ps in the time direction and about 13 μW in the amplitude direction in the embodiment.

As described above, according to the embodiment, an increase in the impedance of the V₁ power supply line can be suppressed. Thus, when the DML drivers sharing the power supply are multichannel-driven by a multistage PRBS signal, the inter-channel crosstalk can be suppressed to suppress the resonance of the power supply line at low frequencies and suppress deterioration of the output waveform.

### Second Embodiment

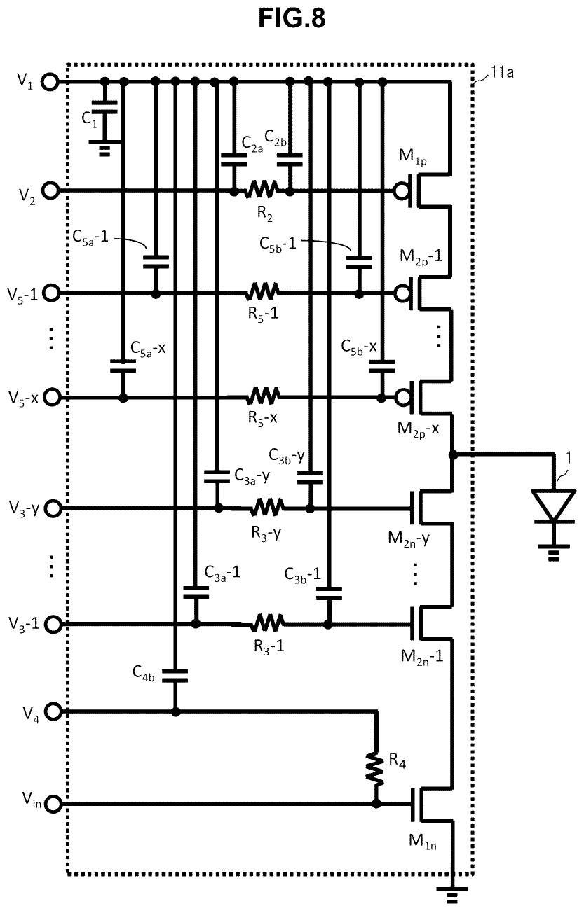

Next, the second embodiment of the present invention will be described. FIG. 8 is a circuit diagram showing the arrangement of a DML driver according to the second embodiment of the present invention. A DML driver 11a according to the embodiment includes a PMOS transistor M₁ₚ; an NMOS transistor M₁ₙ; one or more PMOS transistors M₂ₚ-1 to M₂ₚ-x cascode-connected between the drain of the PMOS transistor M₁ₚ and the anode of an LD 1; one or more NMOS transistors M₂ₙ-1 to M₂ₙ-y cascode-connected between the anode of the LD 1 and the drain of the NMOS transistor M₁ₙ; a resistor R₂; one or more resistors R₃-1 to R₃-y each having one end connected to a corresponding one of bias voltages V₃-1 to V₃-y (third bias voltages), and the other end connected to the gate of a corresponding one of the NMOS transistors M₂ₙ-1 to M₂ₙ-y; a resistor R₄; one or more resistors R₅-1 to R₅-x each having one end connected to a corresponding one of bias voltages V₅-1 to V₅-x (fourth bias voltages), and the other end connected to the gate of a corresponding one of the PMOS transistors M₂ₚ-1 to M₂ₚ-x; decoupling capacitors C₁, C₂ₐ, and C_{2b}; one or more decoupling capacitors C₃ₐ-1 to C₃ₐ-y each having one end connected to a corresponding one of the bias voltages V₃-1 to V₃-y, and the other end connected to the power supply voltage V₁; one or more decoupling capacitors C_{3b}-1 to C_{3b}-y each having one end connected to the gate of a corresponding one of the NMOS transistors M₂ₙ-1 to M₂ₙ-y, and the other end connected to the power supply voltage V₁; a decoupling capacitor C_{4b}; one or more decoupling capacitors C₅ₐ-1 to C₅ₐ-x each having one end connected to a corresponding one of the bias voltages V₅-1 to V₅-x, and the other end connected to the power supply voltage V₁; and one or more decoupling capacitors C_{5b}-1 to C_{5b}-x each having one end connected to the gate of a corresponding one of the PMOS transistors M₂ₚ-1 to M₂ₚ-x, and the other end connected to the power supply voltage V₁.

These voltages have a magnitude relationship: V₁>V₂>V₅-1> . . . >V₅-x>V₃-y> . . . >V₃-1>V₄>GND (ground). The cascode connection of the PMOS transistor may be implemented by connecting its source to the drain of a PMOS transistor at an upper stage, and its drain to the source of a PMOS transistor at a lower stage or the anode of the LD 1. The cascode connection of the NMOS transistor may be implemented by connecting its source to the drain of an NMOS transistor at a lower stage, and its drain to the source of an NMOS transistor at an upper stage or the anode of the LD 1.

In this manner, a multistage circuit arrangement can be adopted to prevent the voltage breakdown of both the PMOS and NMOS transistors. This is effective for a front-end node because the breakdown voltage per single transistor decreases. Here, the PMOS transistors M₂ₚ-1 to M₂ₚ-x cascode-connected to the PMOS transistor M₁ₚ are arranged at x stages, and the NMOS transistors M₂ₙ-1 to M₂ₙ-y cascode-connected to the NMOS transistor M₁ₙ are arranged at y stages. Both x and y are one or more.

In the embodiment, when a multichannel arrangement is employed, each of the power supplies V₁, V₂, V₃-1 to V₃-y, V₄, and V₅-1 to V₅-x, the resistors R₂, R₃-1 to R₃-y, and R₅-1 to R₅-x, and the decoupling capacitors C₁, C₂ₐ, C_{2b}, C_{3b}-1 to C_{3b}-y, C_{4b}, and C_{5b}-1 to C_{5b}-x is shared between the DML drivers of the respective channels, similar to FIG. 6.

### Third Embodiment

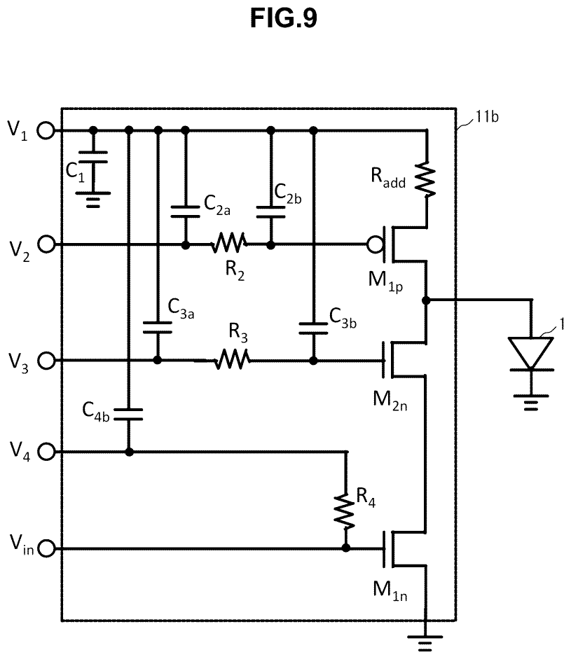

Next, the third embodiment of the present invention will be described. FIG. 9 is a circuit diagram showing the arrangement of a DML driver according to the third embodiment of the present invention. A DML driver 11b according to the embodiment is constituted by inserting a resistor R_{add} between a power supply voltage V₁ and the source of a PMOS transistor M₁ₚ in the DML driver 11 according to the first embodiment. By series-connecting the resistor R_{add} to the source of the PMOS transistor M₁ₚ, the influence of the resonance of the power supply can be suppressed.

In the embodiment, when a multichannel arrangement is employed, each of the power supply V₁, power supplies V₂ to V₄, resistors R₂ and R₃, and decoupling capacitors C₁, C₂ₐ, C_{2b}, C₃ₐ, C_{3b}, and C_{4b} is shared between the DML drivers of the respective channels, similar to FIG. 6. Further, one resistor R_{add} may be inserted between the power supply voltage V₁ and the sources of the PMOS transistors M₁ₚ of the DML drivers of the respective channels, and shared between the DML drivers of the respective channels.

Although the resistor R_{add} is applied to the first embodiment in FIG. 9, it may be applied to the second embodiment.

If the breakdown voltage of the NMOS transistor has no problem, it is possible to omit the NMOS transistor M₂ₙ, and connect the drain of the NMOS transistor M₁ₙ and the anode of the LD 1 in the first and third embodiments. In this case, the resistor R₃, the decoupling capacitors C₃ₐ and C_{3b}, and the bias voltage V₃ become unnecessary.

In the second embodiment, if the breakdown voltage of the PMOS transistor has no problem, it is possible to omit the PMOS transistors M₂ₚ-1 to M₂ₚ-x, and arrange only the PMOS transistor M₁ₚ, similar to the first and third embodiments. In this case, the resistors R₅-1 to R₅-x, the decoupling capacitors C_{5b}-1 to C_{5b}-x, and the bias voltages V₅-1 to V₅-x become unnecessary.

Although the MOS transistors are used as the transistors M₁ₚ, M₂ₚ-1 to M₂ₚ-x, M₁ₙ, and M₂ₙ-1 to M₂ₙ-y in the first to third embodiments, PNP bipolar transistors may be used as the transistors M₁ₚ and M₂ₚ-1 to M₂ₚ-x, and NPN bipolar transistors may be used as the transistors M₁ₙ and M₂ₙ-1 to M₂ₙ-y. When a bipolar transistor is used, the gate should be replaced with a bases, the drain with a collector, and the source with an emitter in the description of the first to third embodiments.

### INDUSTRIAL APPLICABILITY

The embodiments of the present invention can be applied to a technique of directly modulating the optical output of an LD.

### EXPLANATION OF THE REFERENCE NUMERALS AND SIGNS

1. . . . LD, 10. . . . LD array, 11, 11-1 to 11-4, 11a, 11b . . . DML driver, 12 . . . driver IC, M₁ₚ, M₂ₚ-1 to M₂ₚ-x . . . PMOS transistor, M₁ₙ, M₂ₙ-1 to M₂ₙ-y . . . NMOS transistor, R₂, R₃, R₃-1 to R₃-y, R₄, R₅-1 to R₅-x . . . resistor, C₁, C₂ₐ, C_{2b}, C₃ₐ, C_{3b}, C₃ₐ-1 to C₃ₐ-y, C_{3b}-1 to C_{3b}-y, C_{4b}, C₅ₐ-1 to C₅ₐ-x, C_{5b}-1 to C_{5b}-x . . . decoupling capacitor

1.-4. (canceled)

5. A directly modulated laser (DML) driver comprising:
a first transistor having a source or emitter connected to a first power supply terminal, and a drain or collector configured to be connected to an anode of a laser diode;
a second transistor having a gate or base connected to an input signal terminal, a drain or collector configured to be connected to the anode of the laser diode, and a source or emitter connected to a second power supply terminal;
a first resistor having one end connected to a first bias terminal, and the other end connected to a gate or base of the first transistor;
a second resistor having one end connected to a second bias terminal, and the other end connected to a gate or base of the second transistor;
a first decoupling capacitor having one end connected to the first power supply terminal, and the other end connected to the second power supply terminal;
a second decoupling capacitor having one end connected to the first bias terminal, and the other end connected to the first power supply terminal;
a third decoupling capacitor having one end connected to the gate or base of the first transistor, and the other end connected to the first power supply terminal; and
a fourth decoupling capacitor having one end connected to the second bias terminal, and the other end connected to the first power supply terminal.

6. The DML driver according to claim 5, further comprising:
a third transistor cascode-connected between the anode of the laser diode and the drain or collector of the second transistor;
a third resistor having one end connected to a third bias terminal, and the other end connected to a gate or base of the third transistor;
a fifth decoupling capacitor having one end connected to the third bias terminal, and the other end connected to the first power supply terminal; and
a sixth decoupling capacitor having one end connected to the gate or base of the third transistor, and the other end connected to the first power supply terminal.

7. The DML driver according to claim 5, further comprising:
a fourth transistor cascode-connected between the drain or collector of the first transistor and the anode of the laser diode;
a fourth resistor having one end connected to a fourth bias terminal for applying a fourth bias voltage, and the other end connected to a gate or base of the fourth transistor;
a seventh decoupling capacitor having one end connected to the fourth bias terminal, and the other end connected to the first power supply terminal; and
an eighth decoupling capacitor having one end connected to the gate or base of the fourth transistor, and the other end connected to the first power supply terminal.

8. The DML driver according to claim 5, further comprising a fifth resistor inserted between the first power supply terminal and the source or emitter of the first transistor.

9. The DML driver according to claim 6, further comprising:
a fourth transistor cascode-connected between the drain or collector of the first transistor and the anode of the laser diode;
a fourth resistor having one end connected to a fourth bias terminal for applying a fourth bias voltage, and the other end connected to a gate or base of the fourth transistor;
a seventh decoupling capacitor having one end connected to the fourth bias terminal, and the other end connected to the first power supply terminal; and
an eighth decoupling capacitor having one end connected to the gate or base of the fourth transistor, and the other end connected to the first power supply terminal.

10. The DML driver according to claim 6, further comprising a fifth resistor inserted between the first power supply terminal and the source or emitter of the first transistor.

11. The DML driver according to claim 7, further comprising a fifth resistor inserted between the first power supply terminal and the source or emitter of the first transistor.

12. A directly modulated laser (DML) driver, comprising:
a PMOS transistor having a source connected to a first power supply terminal and a drain connected to an anode of a laser diode;
an NMOS transistor having a gate configured to be connected to an modulated input signal, and a source connected to a second power supply terminal;
a resistor having one end connected to a first bias terminal, and the other end connected to the gate of the PMOS transistor;
a first decoupling capacitor having one end connected to the first power supply terminal, and the other end connected to the second power supply terminal; and
a plurality of decoupling capacitors each having one end connected to a respective bias terminal, and the other end connected to the first power supply terminal.

13. The DML driver of claim 12, wherein the PMOS transistor and the NMOS transistor are cascode-connected.

14. The DML driver of claim 12, wherein the resistor is an impedance matching resistor.

15. The DML driver of claim 12, wherein the DML driver is integrated within a driver integrated circuit for a laser diode array.

16. A directly modulated laser (DML) driver system, comprising:
a plurality of DML drivers each having a PMOS transistor with a source connected to a first power supply terminal and a drain connected to an anode of a laser diode, an NMOS transistor with a gate to which a modulated signal is input, and a source connected to a second power supply terminal, a resistor having one end connected to a first bias terminal, and the other end connected to the gate of the PMOS transistor, a first decoupling capacitor having one end connected to the first power supply terminal, and the other end connected to the second power supply terminal, and a plurality of decoupling capacitors each having one end connected to a respective bias terminal, and the other end connected to the first power supply terminal;
wherein the DML drivers share the first power supply terminal, the second power supply terminal, the resistor, the first decoupling capacitor, and the plurality of decoupling capacitors.

17. The DML driver system of claim 16, wherein the PMOS transistor and the NMOS transistor are cascode-connected.
